(19) United States
(12) Patent Application Publication
(10) Pub. No.: US 2011/0270427 A1
(43) Pub. Date: Nov. 3, 2011

(54) DIGITAL/ANALOG CONVERTOR AND DIGITAL AUDIO PROCESSING CIRCUIT ADOPTING THE SAME

(75) Inventors: Yuki TAKAHASHI, Yokohama (JP); Mitsuo Kitamura, Yokohama (JP)

(73) Assignee: FUJITSU SEMICONDUCTOR LIMITED, Yokohama-shi (JP)

(21) Appl. No.: 13/069,148

(22) Filed: Mar. 22, 2011

(30) Foreign Application Priority Data
Apr. 30, 2010 (JP) 2010-104706

(51) Int. Cl. G06F 17/00; H03M 1/82

(52) U.S. Cl. 700/94; 341/152

(57) ABSTRACT

A digital analog convertor has a modulator which modulates a digital signal to generate a pulse signal having a pulse density corresponding to a digital value of the digital signal; a first RZ conversion circuit which RZ-converts the pulse signal based on a first clock signal to generate a first RZ pulse signal; a first integration circuit which integrates the first RZ pulse signal to output a first analog signal; a second RZ conversion circuit which RZ-converts a first level signal having a first level of the pulse signal based on the first clock signal to generate a second RZ pulse signal; a second integration circuit which integrates the second RZ pulse signal to output a second analog signal; and a clock duty control circuit which controls a duty ratio of the first clock signal so that the second analog signal approaches a given reference level.

### CROSS-REFERENCE TO RELATED APPLICATION

This application is based upon and claims the benefit of priority of the prior Japanese Patent Application No. 2010-104706, filed on Apr. 30, 2010, the entire contents of which are incorporated herein by reference.

### FIELD

The embodiment relates to a digital/analog convertor and a digital audio processing circuit adopting the digital/analog convertor.

### BACKGROUND

A digital/analog convertor (DAC) is a circuit for converting digital signals into analog signals. Recently digital audio processing circuits, which convert digital audio signals, such as music, into analog signals and regenerate audio data by the analog signals, are widely used. Examples are a voice recorder, music regeneration apparatus and portable telephone.

There are various types of configurations of DAC, but a ΔΣ modulation type DAC using a ΔΣ modulator is widely used. An example is disclosed in Japanese Patent Application Laid-Open No. 2008-167072.

A ΔΣ modulation type DAC has a ΔΣ modulator and an integrator. The ΔΣ modulator converts a digital signal into a pulse string having a pulse density corresponding to the digital value. An analog signal can be generated by integrating this pulse string by the integrator.

The voltage of a pulse signal generated by a ΔΣ modulator fluctuates due to the influence of power supply noise. This voltage fluctuation of the pulse signal causes fluctuation of an analog signal generated by an integrator, and drops analog signal conversion accuracy.

### SUMMARY

A digital analog convertor includes a modulator which modulates a digital signal having a plurality of bits to generate a pulse signal having a pulse density corresponding to a digital value of the digital signal; a first RZ conversion circuit which RZ-converts the pulse signal based on a first clock signal to generate a first RZ pulse signal; a first integration circuit which integrates the first RZ pulse signal to output a first analog signal; a second RZ conversion circuit which RZ-converts a first level signal having a first level of the pulse signal based on the first clock signal to generate a second RZ pulse signal; a second integration circuit which integrates the second RZ pulse signal to output a second analog signal; and a clock duty control circuit which controls a duty ratio of the first clock signal so that the second analog signal approaches a given reference level.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of a digital/analog convertor (DAC).

FIG. 2 is a diagram depicting the RZ conversion of the RZ convertor 2.

FIG. 3 is a block diagram of the ΔΣ modulation type DAC according to the embodiment.

FIG. 4 is a graph illustrating duty ratio control by the clock duty control circuit 22.

FIG. 5 is a diagram depicting a first example of the ΔΣ modulation type DAC in FIG. 1 and FIG. 3.

FIG. 6 is a diagram depicting the configuration and operation of the clock duty control circuit 22 in FIG. 5.

FIG. 7 is a diagram depicting a second example of the ΔΣ modulation type DAC in FIG. 1 and FIG. 3.

FIG. 8 is a diagram depicting the operation thereof.

FIG. 9 is a diagram depicting a third example of the ΔΣ modulation type DAC in FIG. 1 and FIG. 3.

FIG. 10 is a diagram depicting the operation thereof.

FIG. 11 is a diagram depicting a fourth example of the ΔΣ modulation type DAC in FIG. 1 and FIG. 3.

FIG. 12 is a block diagram of the ΔΣ modulation type DAC according to the second embodiment.

FIG. 13 is a flow chart depicting the duty ratio control of the clock duty control circuit 30 of the DAC in FIG. 12.

FIG. 14 is a diagram depicting control of the duty ratio of the clock signal of the DAC according to the second embodiment.

FIG. 15 is a block diagram depicting the clock duty control circuit 30 of the DAC according to the second embodiment.

FIG. 16 is a diagram depicting the operation thereof.

FIG. 17 is a diagram depicting a first variant form of the duty ratio control of the clock duty control circuit 30 of the DAC according to the second embodiment.

FIG. 18 is a diagram depicting a second variant form of the duty ratio control of the clock duty control circuit 30 of the DAC according to the second embodiment.

FIG. 19 is a configuration example of the ΔΣ modulator.

FIG. 20 is a block diagram of a digital audio processing circuit which has the ΔΣ modulation type DAC according to the first or second embodiment.

### DESCRIPTION OF EMBODIMENTS

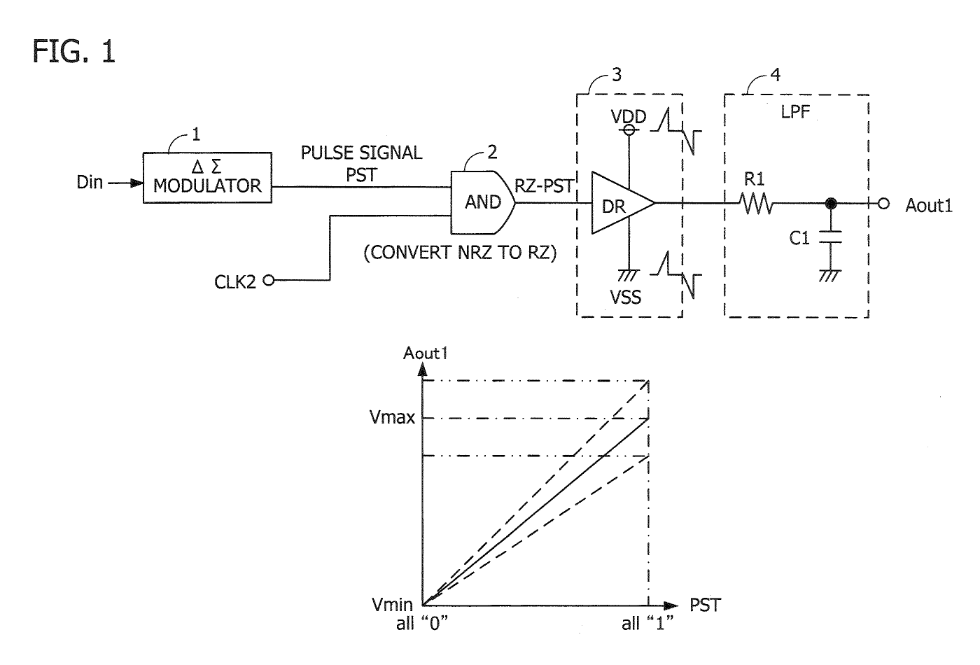

FIG. 1 is a block diagram of a digital/analog convertor (DAC). This DAC converts a digital signal Din into an analog signal Aout1. The DAC illustrated in FIG. 1 is a delta sigma modulation type DAC, and has: a ΔΣ modulator 1 which modulates a digital signal Din and converts it into a pulse signal PST having a pulse density corresponding to a digital value of the digital signal; and an RZ convertor 2 which performs RZ (Return to Zero) conversion on the pulse signal PST based on the clock CLK2 to generate an RZ-converted pulse RZ-PST. The RZ convertor 2 is an AND circuit, for example.

The DAC also has a driver circuit 3 which shapes the waveform of the RZ pulse signal RZ-PST, and an integration circuit 4 which integrates an output signal of the driver and outputs an analog signal Aout1. The driver circuit 3 is a CMOS buffer circuit, for example, which is coupled to a power supply VDD and a ground VSS, and supplies current from the power supply VDD when the RZ pulse signal RZ-PST is at H level, and absorbs current to the ground VSS when the RZ pulse signal RZ-PST is at L level. Therefore the integration circuit 4 generates an analog signal Aout1 of which voltage is higher as the density of H level of the RZ pulse signal RZ-PST is higher, and generates an analog signal Aout1 of which voltage is lower as the density of L level thereof is higher.

The integration circuit 4 is a low pass filter LPF comprised of a register R1 and a capacitor C1, for example. As a result, the analog signal Aout1 generated by the integration circuit 4 is an analog signal having a voltage level according to the pulse density of the RZ pulse signal RZ-PST.

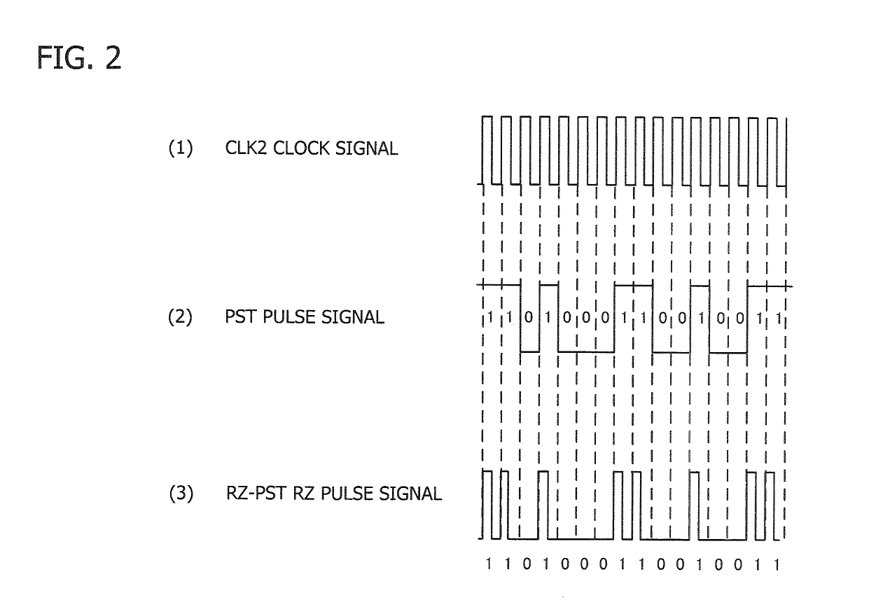

FIG. 2 is a diagram depicting the RZ conversion of the RZ convertor 2. The RZ convertor 2 in FIG. 1 is an AND gate. As FIG. 2 illustrates, the pulse signal PST is a pulse signal having a bit stream of “1” and “0” generated by the ΔΣ modulator 1. The AND gate 2 performs the AND operation on a clock signal CLK2, which has a same frequency as the pulse signal PST, and the pulse signal PST, and outputs an RZ pulse signal RZ-PST.

The RZ pulse signal RZ-PST is a pulse signal which returns to zero potential (L level) at every cycle of the clock signal CLK2. As a result, an RZ pulse signal, when the pulse signal PST is “1” after “0”, has a same waveform as an RZ pulse signal when the pulse signal is “1” after “1”, so the generation of a pattern dependency of the pulse signal PST on the voltage level of the analog signal Aout1 generated by the integration circuit 4 may be avoided.

The RZ convertor 2 may perform conversion so that the RZ pulse signal RZ-PST becomes a pulse signal which returns to a power supply voltage (H level) at every clock signal cycle based on the same principle. In this case, the RZ convertor may be a NAND gate, instead of an AND gate. The RZ pulse signal in this case, however, becomes H level when the pulse signal PST is “0”, and becomes L level and H level when the pulse signal PST is “1”. This means that the RZ pulse signal and the analog signal Aout1 are inverted from the case of FIG. 2.

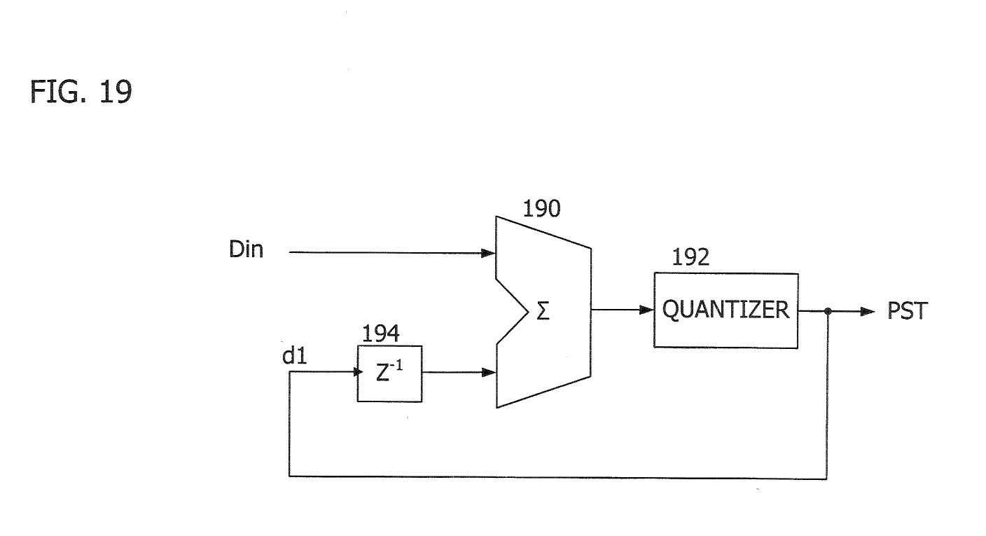

FIG. 19 is a configuration example of the ΔΣ modulator. The ΔΣ modulator has an adder 190, a quantizer 192 and a delay circuit 194. The adder 190 outputs an integrated value of the digital signal Din by adding the previous digital signal d1 to the digital signal Din. The quantizer 192 compares the integrated value with a reference value to quantize it, and outputs the pulse signal PST which has “1” and “0” bit streams. If the quantizer 192 outputs “1”, the difference of the integrated value and the reference value is fed back as digital signal d1. By this configuration, the ΔΣ modulator generates a pulse signal PST with a pulse density corresponding to the digital value of the input digital signal Din.

Referring to FIG. 1 again, if noise is generated in the power supply VDD or the ground VSS and the voltage (VDD−VSS) fluctuates, the potential of the analog signal Aout1 fluctuates accordingly. As FIG. 1 illustrates, the analog signal Aout1 becomes maximum potential Vmax when the pulse signals PST in a given period are all “1”, and becomes minimum potential Vmin when all are “0”, and the potential of the analog signal Aout1 increases linearly as a number of “1” in the pulse signal PST increases.

However the potential of the analog signal Aout1 fluctuates as illustrated by the broken line, due to the generation of the power supply noise. As a result, the potential of the analog signal Aout1 fluctuates as well depending on the power supply noise, and accuracy thereof drops. The fluctuation of the analog signal is also generated by the jitter (fluctuation) of the clock signal CLK2, even without power supply noise. The clock signal CLK2 is generated by a PLL synthesizer or the like, but normally it is difficult to prevent the generation of jitter. This fluctuation of the analog signal generates a digital analog conversion error, which is not desirable.

### First Embodiment

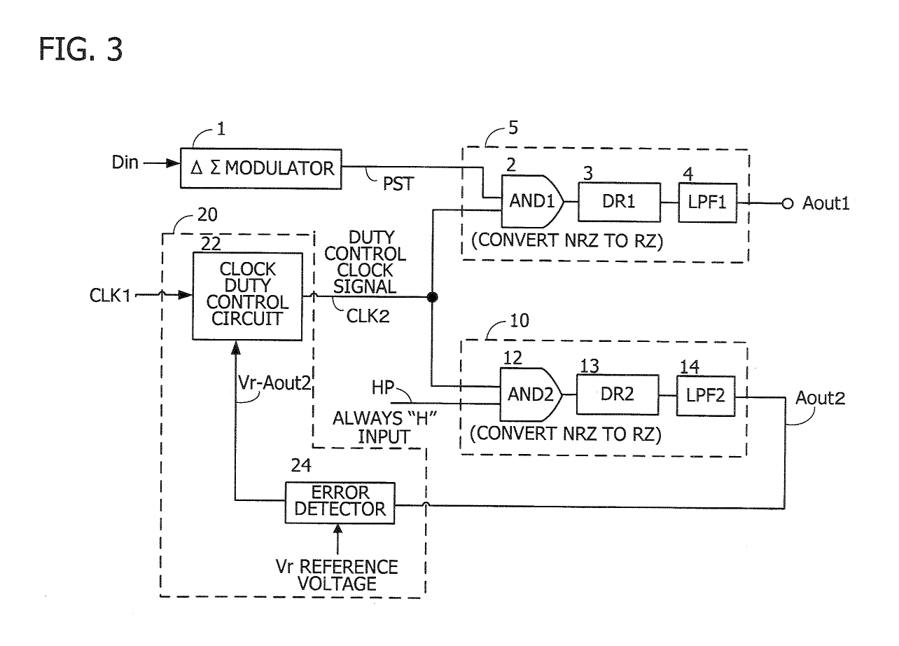

FIG. 3 is a block diagram of the ΔΣ modulation type DAC according to the embodiment. This digital analog convertor (DAC) has a ΔΣ modulator 1 which generates a pulse signal PST, that is a bit stream, from an input digital signal Din, a RZ convertor 2 which converts the pulse signal PST into an RZ pulse signal, a driver 3 and an integrator 4, like FIG. 1, and the integrator 4 outputs an analog signal Aout1. The configuration and operation thereof are the same as FIG. 1.

The DAC in FIG. 3 further has a replica circuit 10 which RZ-converts a pulse signal HP, which is at H level, and integrates the result to generate a replica analog signal Aout2, and a clock duty control circuit 20 which controls the duty ratio of the clock signal CLK2 so that the replica analog signal Aout2 approaches a reference level Vr according to the level of Aout2. The replica circuit 10 for generating the replica analog signal Aout2 has an RZ convertor 12, driver 13 and integrator 14, like circuit 5, and the circuit configuration thereof is the same as the circuit 5. Since a pulse signal HP, which is at H level, is input to the RZ convertor 12 of the replica circuit 10, instead of the pulse signal PST, the potential of the replica analog signal Aout2 is the maximum value Vmax illustrated in FIG. 1.

This replica analog signal Aout2 includes fluctuation components which depend on power supply noise and jitter of the clock signal, like the analog signal Aout1. Particularly the fluctuation components included in the replica analog signal Aout2 are maximized since the pulse signal HP, which is at H level, is used. Therefore the pulse signal HP may be a known bit stream of “1” and “0”, at least including “1”. If all are “1”, the fluctuation components are maximized and the sensitivity of the duty ratio control are enhanced.

This replica analog signal Aout2 is compared with the reference voltage Vr by an error detector 24, and the difference thereof. Vr−Aout2 is input to a clock duty circuit 22 as an error. The clock duty control circuit 22 adjusts the duty ratio of the clock signal CLK1 from a clock generator, such as a PLL synthesizer, according to this error, and generates a clock signal CLK2 in which the duty ratio is controlled. This duty ratio is adjusted such that the potential of the replica analog signal Aout2 approaches the reference voltage Vr.

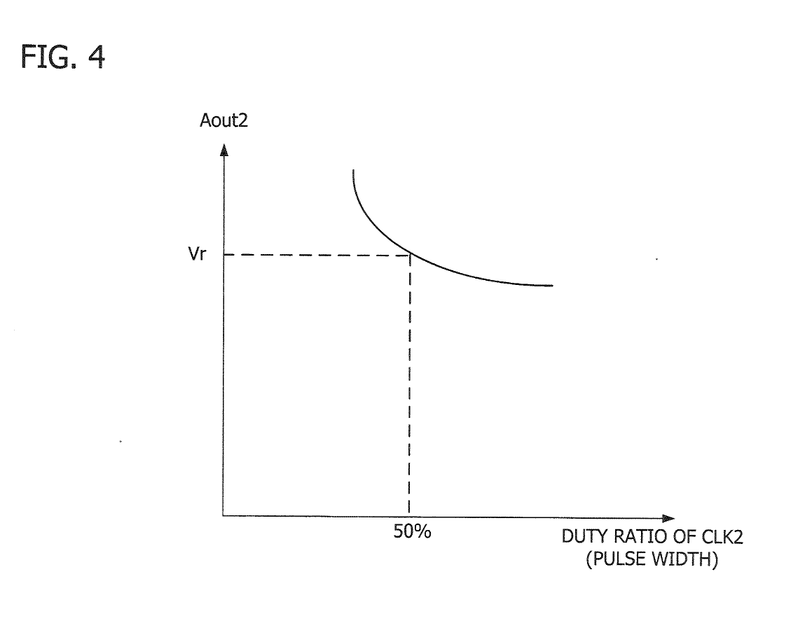

FIG. 4 is a graph illustrating duty ratio control by the clock duty control circuit 22. The abscissa is the duty ratio of the clock signal CLK2, and the ordinate is the replica analog signal Aout2. In the case of FIG. 4, the logic of the circuits 5 and 10 is based on that the voltage levels of the analog signal Aout1 and the replica analog signal Aout2 increases as the duty ratio of the clock signal CLK2 increases, that is, as the pulse width of the H level increases.

As FIG. 4 illustrates, when the replica analog signal Aout2 matches with the reference voltage Vr, the duty ratio of the clock signal CLK2 is controlled to 50%, for example. If the replica analog signal Aout2 exceeds the reference voltage Vr, the clock duty control circuit 22 controls the duty ratio of the clock signal CLK2 to be decreased, and if the Aout2 becomes lower than the reference voltage Vr, the clock duty control circuit 22 controls the duty ratio of the clock signal CLK2 to be increased. By controlling the duty ratio of the clock signal CLK2 like this, the error components included in the replica analog signal Aout2 are suppressed, and fluctuation components included in the analog signal Aout1 are also suppressed. As a result, the digital analog conversion accuracy is increased.

For the fluctuation components of the replica analog signal Aout2 and the fluctuation components of the analog signal Aout1 to have the same tendency, it is preferable that the circuit 5 and the circuit 10 have a same circuit configuration and circuit size at the transistor level, and have a same wiring impedances at the layout level, and are disposed to be as symmetric as possible with reference to the power supply and ground wiring.

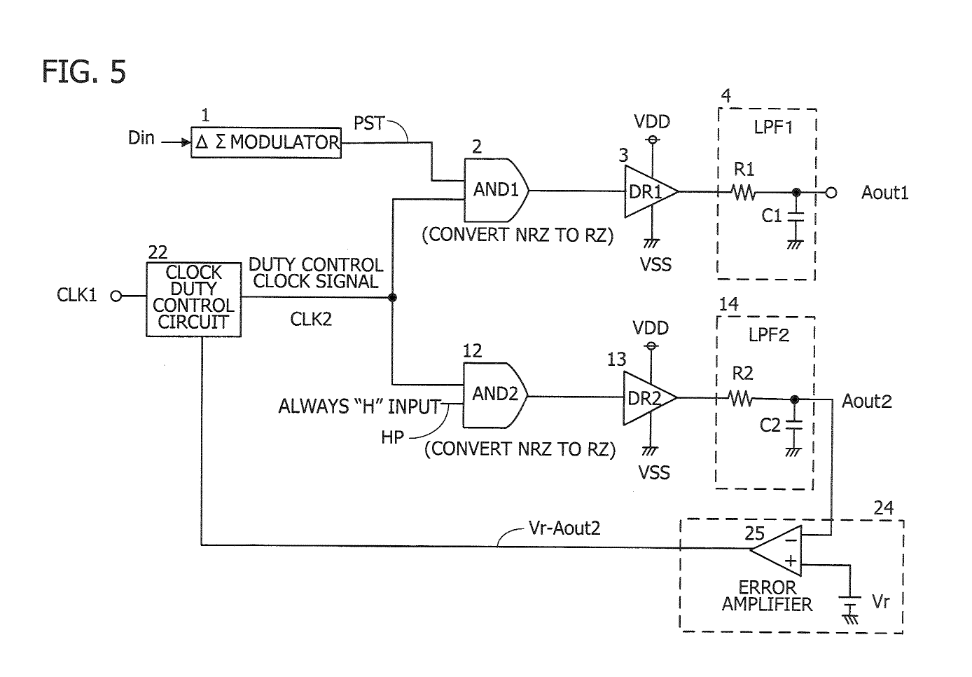

FIG. 5 is a diagram depicting a first example of the ΔΣ modulation type DAC in FIG. 1 and FIG. 3. The driver circuits 2 and 12 are buffer circuits disposed between the power supply VDD and ground VSS, and are two stages of CMOS invertors, for examples. Similar to FIG. 1, the integrators 4 and 14 are low pass filters comprised of resistors R1 and R2 and capacitors C1 and C2 respectively. The integrators 4 and 14 generate smoothed analog signals Aout1 and Aout2 by integrating the H level signals and L level signals from the drivers 3 and 13.

The error detector 24 in FIG. 5 has an error amplifier 25 constituted by an operational amplifier 25, where the replica analog signal Aout2 and the reference voltage Vr are input, and the difference thereof. Vr−Aout2 is output. The clock duty control circuit 22 controls the duty ratio of the clock CLK2 to be increased if this difference Vr−Aout2 is positive, and controls it to be decreased if this difference Vr−Aout2 is negative. In other words, the replica analog signal Aout2 is controlled to approach the reference voltage Vr by negative feedback control.

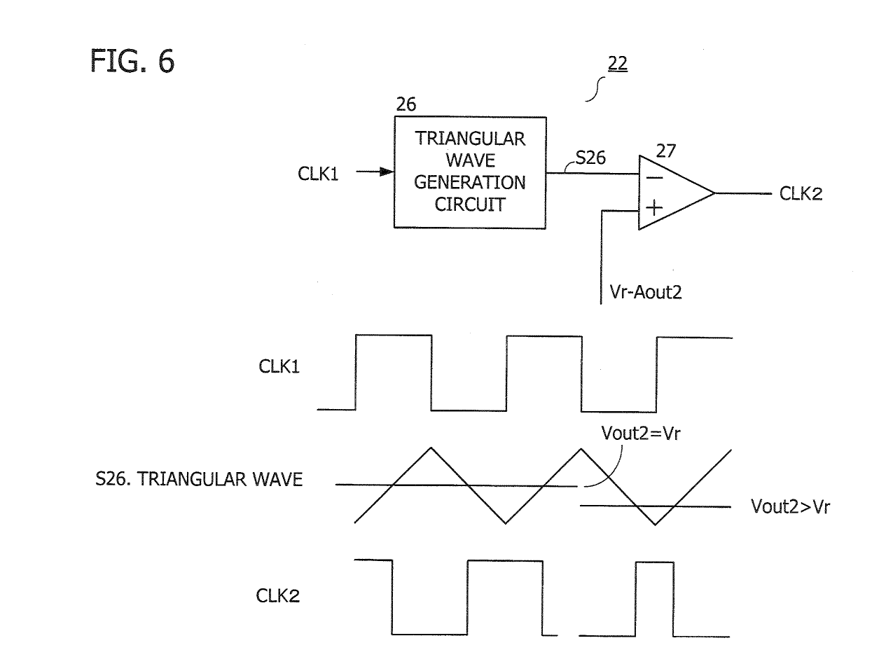

FIG. 6 is a diagram depicting the configuration and operation of the clock duty control circuit 22 in FIG. 5. The clock duty control circuit 22 has a triangular wave generation circuit 26 which generates a triangular wave S26 from a clock signal CLK1, and a comparator 27 which compares the triangular wave S26 and an error Vr−Aout2. The clock signal CLK1 is a clock of which duty ratio is 50%, for example, and the triangular wave S26 generated therefrom is as illustrated in FIG. 6. In the case of the error Vr−Aout2=0, the clock signal CLK2, which is output by the comparator 27, has a duty ratio of 50%, which is the same as the clock signal CLK1. In the case of the error Vr−Aout2<0, the duty ratio of the clock signal CLK2, which is output by the comparator 27, is adjusted to be lower than 50%. In the case of the error Vr−Aout2>0, on the other hand, the duty ratio of the clock signal CLK2, which is output by the comparator 27, is adjusted to be higher than 50%.

In the case of a configuration where inversion logic is included in the RZ convertor 12, driver circuit 13, integrator 14 or the like, the above mentioned control of the duty ratio of the clock signal CLK2 is reversed. In other words, in the case of the error Vr−Aout2<0, the duty ratio of the clock signal CLK2, which is output by the comparator 27, is adjusted to be higher than 50%. In the case of the error Vr−Aout2>0, on the other hand, the duty ratio of the clock signal CLK2, which is output by the comparator 27, is adjusted to be lower than 50%.

In any case, the clock duty control circuit 22 controls the duty ratio of the clock CLK2 such that the replica analog signal Aout2 approaches the reference voltage Vr.

If the RZ conversion circuit 2 and 12, which are AND gates, in FIG. 5, have sufficient output drive capability, the driver circuits 3 and 13 may be omitted. The AND gates are CMOS circuits coupled to the power supply VDD and the ground VSS, for example.

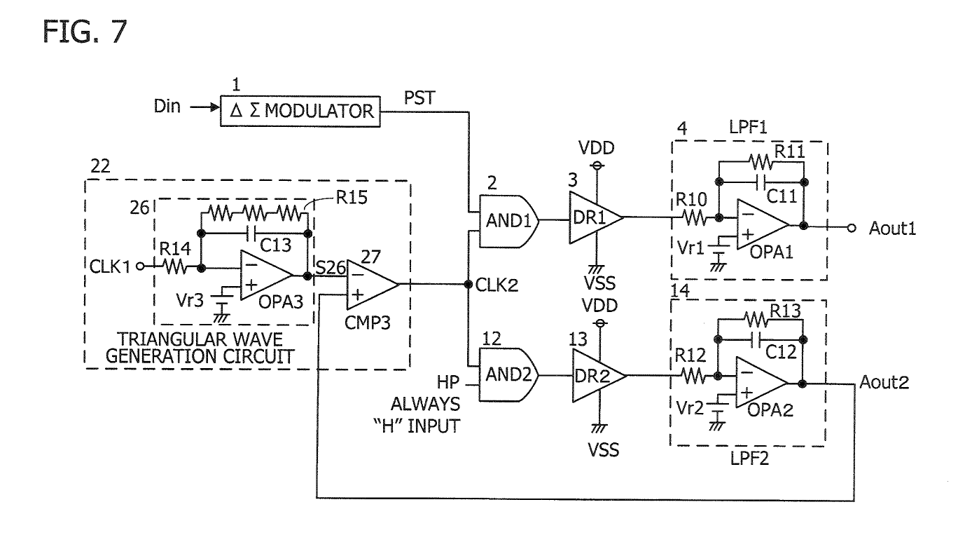

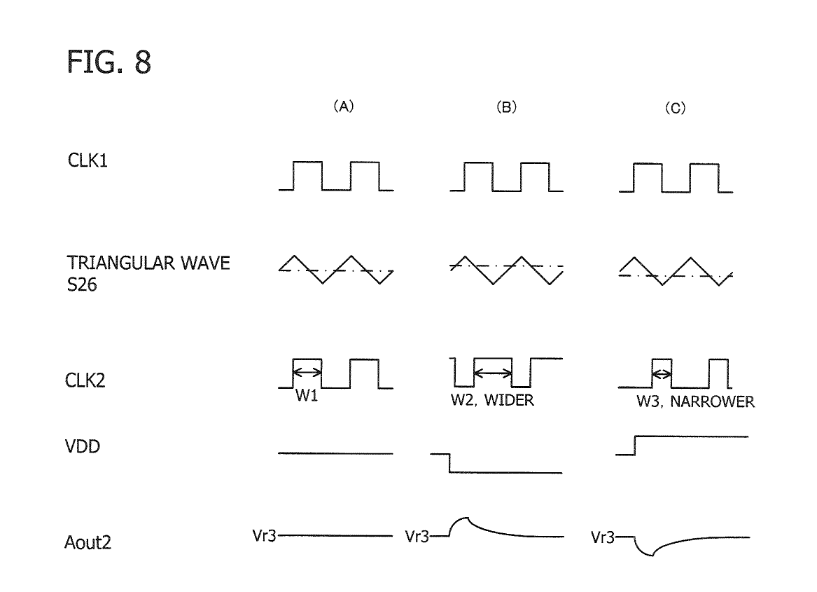

FIG. 7 is a diagram depicting a second example of the ΔΣ modulation type DAC in FIG. 1 and FIG. 3. FIG. 8 is a diagram depicting the operation thereof. In this example, the integrators 4 and 14, which are low pass filters, are comprised of operational amplifiers OPA1 and OPA2, resistors R10, R11, R12 and R13, capacitors C11 and C12, and reference voltages Vr1 and Vr2 respectively. The operational amplifiers OPA1 and OPA2 have inverted logic respectively. The triangular wave generation circuit 26 of the clock duty control circuit 22 as well is comprised of an operational amplifier OPA3, resistors R14 and R15, capacitor C13 and reference voltage Vr3. The replica analog signal Aout2 is directly input to the comparator 27. The reference voltages Vr1, Vr2 and Vr3 are voltages of VDD/2, for example.

Concerning the operation of the integrator 14, when the power supply VDD increases and the output of the driver circuit 13 increases, the output Aout2 of the operational amplifier OPA2 gradually decreases, as illustrated in FIG. 8. On the other hand, when the power supply VDD decreases and the output of the driver circuit 13 decreases, the output Aout2 of the operational amplifier OPA2 gradually increases. In other words, the output Aout2 of this operational amplifier OPA2 has the same logic as the error signal Vr−Aout2 in FIG. 5. The integrator 4 operates in the same manner.

The triangular wave generation circuit 26 also has a similar circuit configuration as the integration circuits 4 and 14. As illustrated in FIG. 8, electric charges are stored in the capacitor C13, and the triangular wave S26 drops while the clock signal CLK1 is at H level, and electric charges are drained from the capacitor C13 and the triangular wave S26 rises while the clock signal CLK1 is at L level.

As FIG. 8 illustrates, when the power supply VDD has no noise components and the replica analog signal Aout2 is in a similar level as reference voltage Vr3, that is in the case of FIG. 8A, the pulse width W1 of the clock CLK2 is 50% of the clock cycle, and the duty ratio is 50%. If the power supply VDD drops due to the generation of negative noise, that is in the case of FIG. 8B, the replica analog signal Aout2 becomes higher than the reference voltage Vr3, the comparator 27 increases the pulse width W2 of the clock signal CLK2, and the duty ratio exceeds 50%. As a result, the replica analog signal Aout2 approaches the reference voltage Vr3. On the other hand, if the power supply VDD increases due to the generation of positive noise, that is the case of FIG. 8C, the replica analog signal Aout2 becomes lower than the reference voltage Vr3, the comparator 27 decreases the pulse width W3 of the clock signal CLK2, and the duty ratio decreases. As a result, the replica analog signal Aout2 approaches the reference voltage Vr3.

If jitter is included in the clock CLK1, this influences the triangular wave S26, and the duty ratio of the clock signal CLK2 is controlled by the comparator 27, so that fluctuation components in the analog signals Aout1 and Aout2, due to jitter of the clock CLK1, are suppressed.

Furthermore, according to the DAC of this embodiment, the fluctuation components in the analog signals Aout1 and Aout2, generated because of the power supply noise and jitter of the clock CLK1, are suppressed by controlling the duty ratio of the reference clock CLK2 of the RZ convertors 2 and 12. This control of the duty ratio is reflected on the analog signals Aout1 and Aout2 via a plurality of cycles of the clock CLK2 by the integration operation of the integrators 4 and 14. Therefore according to the duty ratio control of the clock CLK2, the analog signals Aout1 and Aout2 are finely adjusted. This is the same for the DAC in FIG. 3 and FIG. 5.

When DC offset is generated in the clock CLK1, this is reflected on the triangular wave S26, and the pulse width of CLK2 changes. Since the DC offset components of the clock signal CLK1 are also input to the comparator 27 along with the fluctuation components of the replica analog signal Aout2, the duty ratio of the clock CLK2 is controlled such that the fluctuation components and the DC offset components are cancelled, and as a result, the fluctuation components, due to DC offset of the clock CLK1, are also suppressed.

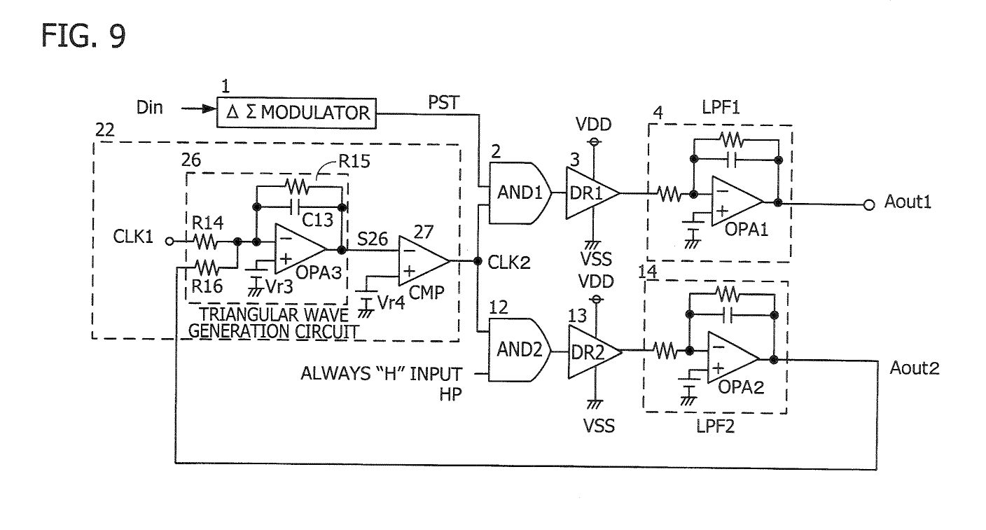

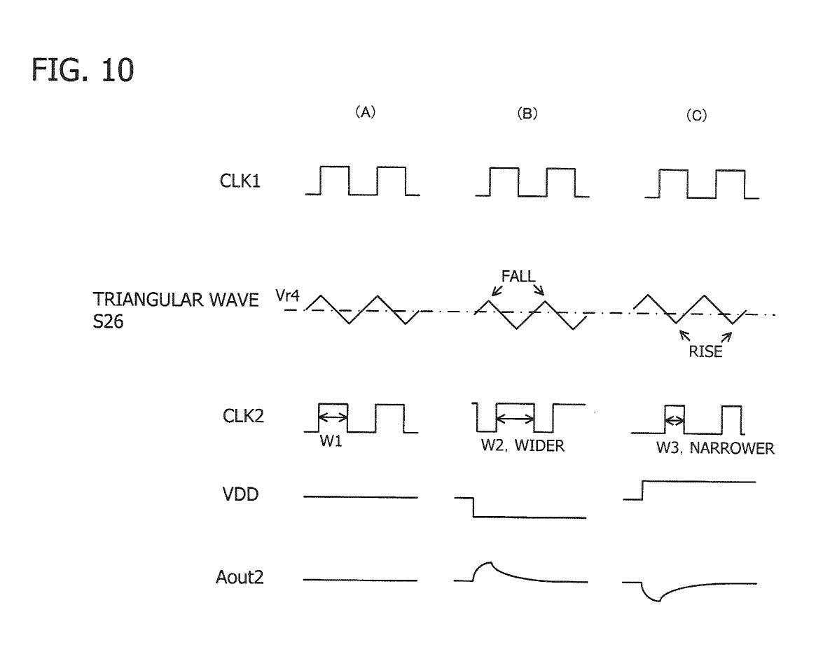

FIG. 9 is a diagram depicting a third example of the AZ modulation type DAC in FIG. 1 and FIG. 3. FIG. 10 is a diagram depicting the operation thereof. In this example, a difference from the DAC in FIG. 7 is the configuration of the clock duty control circuit 22, and the rest of the configuration is the same as FIG. 7. In the case of the clock duty control circuit 22 in FIG. 9, the replica analog signal Aout2 is input to the negative side input of the triangular wave generation circuit 26 via the resistor R16, and the comparator 27 compares the triangular wave S26 with the reference voltage Vr4. This reference voltage Vr4 is VDD/2, for example, like Vr3.

By this configuration, the fluctuation components of the replica analog signal Aout2 are reflected on the triangular wave S26. Then the comparator 27 generates the clock CLK2 of which duty ratio is controlled, like FIG. 7, by comparing the triangular wave S26 including the fluctuation components with the reference voltage Vr4.

If DC offset is included in the clock signal CLK1, the DC offset is also reflected on the triangular wave S26. Since the DC offset components of the clock signal CLK1 are reflected on the triangular wave S26 along with the fluctuation components of the replica analog signal Aout2, the duty ratio of the clock CLK2 is controlled so as to cancel this fluctuation components and DC offset component, like the case of FIG. 7.

As illustrated in FIG. 10, if noise is not generated in the power supply VDD, as illustrated in FIG. 10A, the triangular wave S26 oscillates with the reference voltage Vr4 at the center, and the pulse width W1 of the clock CLK2 is 50% of the pulse cycle and the duty ratio is also 50%. If negative noise is generated in the power supply VDD and the voltage level drops, as illustrated in FIG. 10B, the replica analog signal Aout2 rises and the center of the triangular wave S26 becomes lower than the reference voltage Vr4. Accordingly, the comparator 27 increases the pulse width W2 of the clock signal CLK2, and the duty ratio becomes higher than 50%. As a result, the rise of the replica analog signal Aout2 is suppressed, and the signal level approaches the reference voltage. On the other hand, if positive noise is generated in the power supply VDD and the voltage level rises, as illustrated in FIG. 10C, the replica analog signal Aout2 drops, and the center of the triangular wave S26 becomes higher than the reference voltage Vr4, and the comparator 27 decreases the pulse width W3 of the clock signal CLK2, and the duty ratio decreases. As a result, a drop in the replica analog signal Aout2 is suppressed, and the signal level approaches the reference voltage.

In the case when jitter is generated in the clock CLK1 and the replica analog signal Aout2 deviates from the reference voltage as well, the duty ratio of the clock signal CLK2 is controlled in the same manner as above, and the level of the replica analog signal Aout2 is adjusted.

If plus DC offset is generated in the clock signal CLK1, the voltage level of the triangular wave S26 drops and the duty ratio of the clock signal CLK2 increases, the level of the replica analog signal Aout2 drops, and the plus DC offset of the clock signal CLK1 is cancelled by the resistors R14 and R16 in the input side of the triangular wave generation circuit 26. If minus DC offset is generated, the DC offset is cancelled by a reverse operation of above.

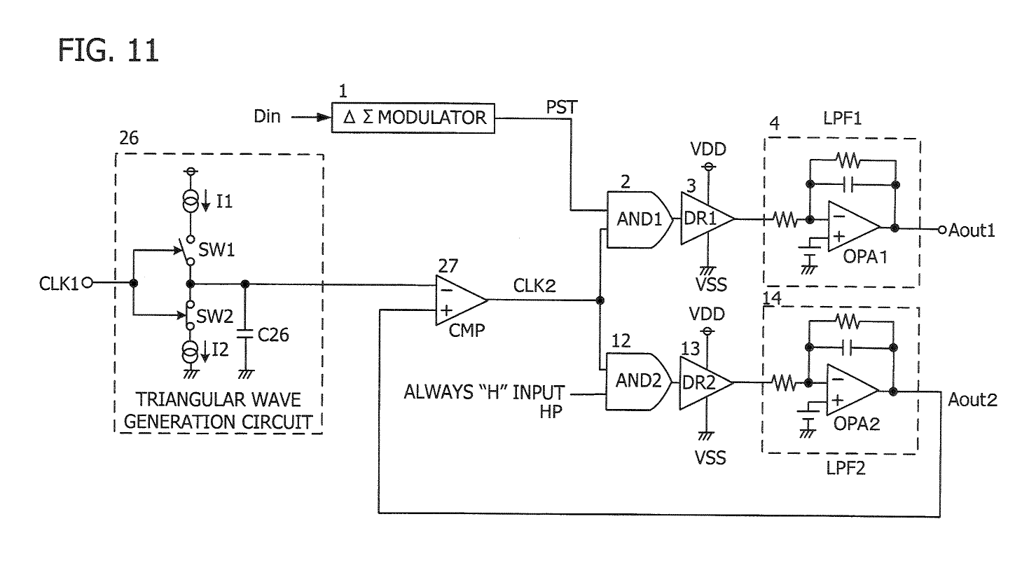

FIG. 11 is a diagram depicting a fourth example of the ΔΣ modulation type DAC in FIG. 1 and FIG. 3. In this DAC, the triangular wave generation circuit 26 of the DAC in FIG. 7 is constituted by a charge pump circuit. The rest of the configuration is the same as FIG. 7.

The triangular generation circuit 26 of the DAC in FIG. 11 is constituted by a charge pump circuit, constituted by a capacitor C26, current sources 11 and 12, and switches SW1 and SW2, instead of an operational amplifier. The switch SW1 is, for example, a P-channel MOS transistor, the switch SW2 is, for example, an N-channel MOS transistor, and these are a pull-up switch and pull-down switch respectively. While the clock signal CLK1 is at L level, the switch SW1 turns ON and the constant current I1 charges the capacitor C26, and while the clock signal CLK1 is at H level, the switch SW2 turns ON and the capacitor C26 discharges by the constant current I2, and the triangular wave S26 is generated. Since this triangular wave generation circuit 26 does not use the operational amplifier in FIG. 7, the circuits are simplified, and the circuit area of the DAC on chip is decreased.

### Second Embodiment

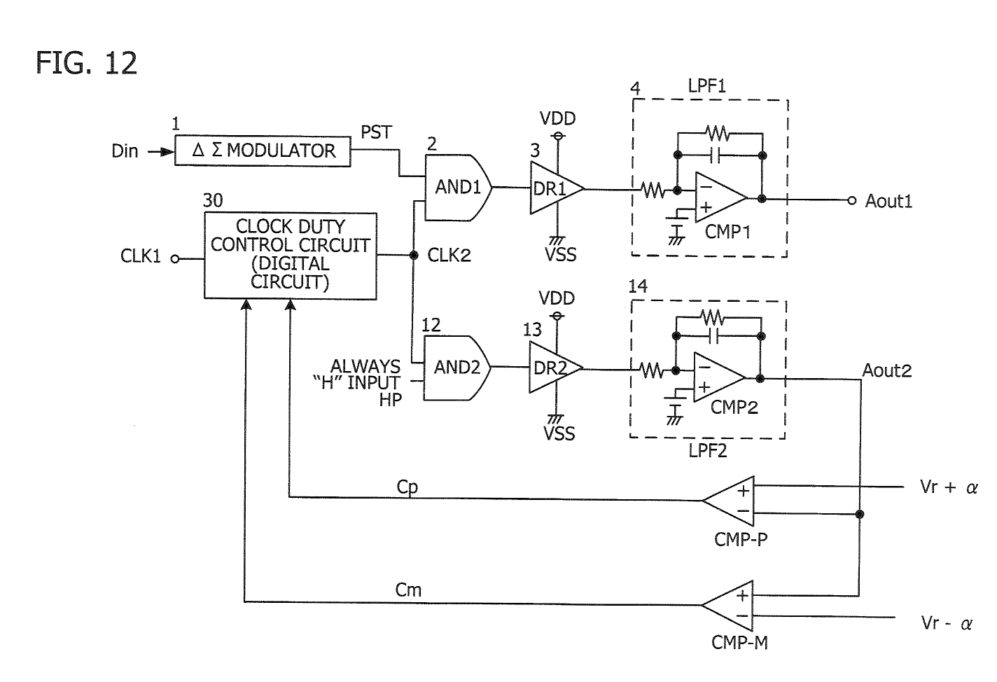

FIG. 12 is a block diagram of the ΔΣ modulation type DAC according to the second embodiment. In this DAC, the clock duty control circuit 30 is not constituted by a triangular wave generation circuit and comparator, but is constituted by a digital circuit (logic circuit) which increases or decreases the pulse width of the clock CLK1 based on adjustment signals Cp and Cm, which are obtained by comparison of the replica analog signal Aout2 and the reference voltage Vr+α and Vr−α. The adjustment signals Cp and Cm are generated by the comparators CMP-P and CMP-M. The rest of the configuration is the same as the DAC in FIG. 7.

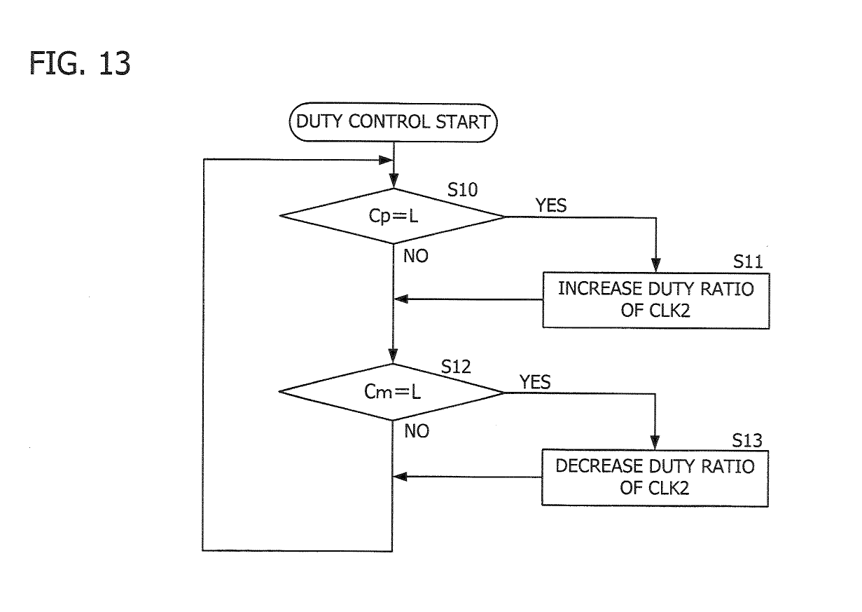

FIG. 13 is a flow chart depicting the duty ratio control of the clock duty control circuit 30 of the DAC in FIG. 12. When the replica analog signal Aout2 becomes higher than the reference voltage Vr+α, the adjustment signal Cp becomes Cp=L, and the clock duty control circuit 30 increases the duty ratio of the clock signal CLK2 so that the outputs of the drivers 3, 13 become higher. As a result, the replica analog signal Aout2, which is the output of the integration circuit 14 having inverted logic, drops. On the other hand, when the replica analog signal Aout2 becomes lower than the reference voltage Vr−α, the adjustment signal Cm becomes Cm=L, and the clock duty control circuit 30 decreases the duty ratio of the clock signal CLK2 so that the outputs of the drivers 3, 13 become lower. As a result, the replica analog signal Aout2 rises. If the replica analog signal Aout2 is between Vr+α and Vr−α and so both Cp and Cm are at H level, the duty ratio is not changed.

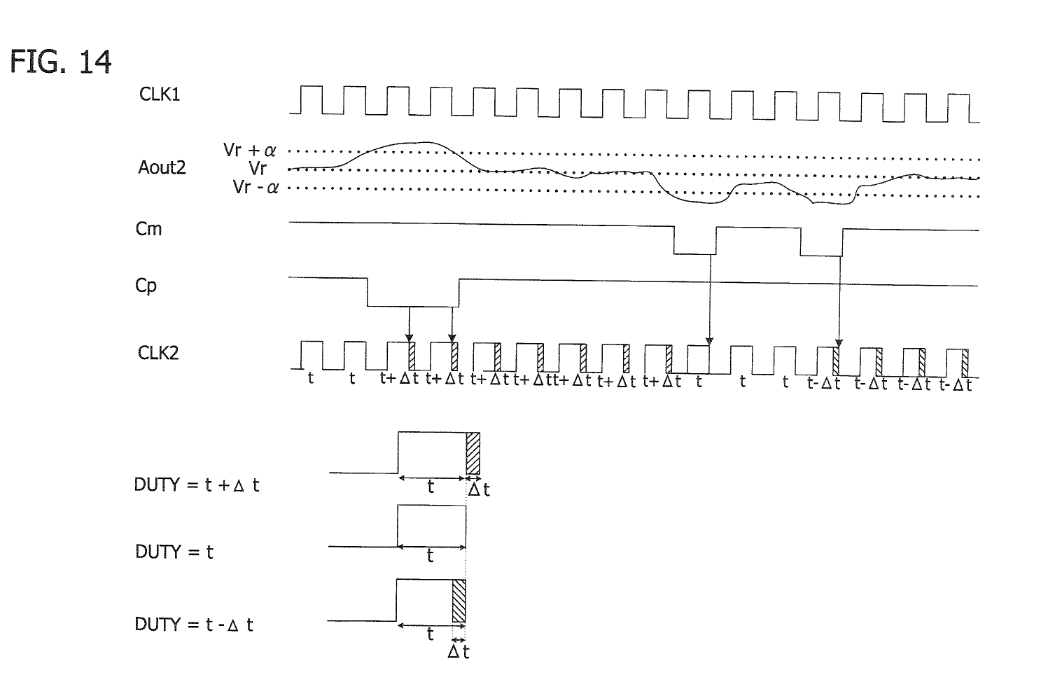

FIG. 14 is a diagram depicting control of the duty ratio of the clock signal of the DAC according to the second embodiment. When the replica analog signal Aout2 becomes higher than the reference voltage Vr+α, and the adjustment signal Cp becomes Cp=L, the clock duty control circuit 30 increases the pulse width of the clock signal CLK2 to t+Δt. On the other hand, if the replica analog signal Aout2 becomes lower than the reference voltage Vr−α, and the adjustment signal Cm becomes Cm=L, the clock duty control circuit 30 decreases the pulse width of the clock signal CLK2 to t−Δt. If the replica analog signal Aout2 is between the reference voltage Vr+α and Vr−α, the clock duty control circuit 30 maintains the pulse width of the clock signal CLK2 without increasing or decreasing it.

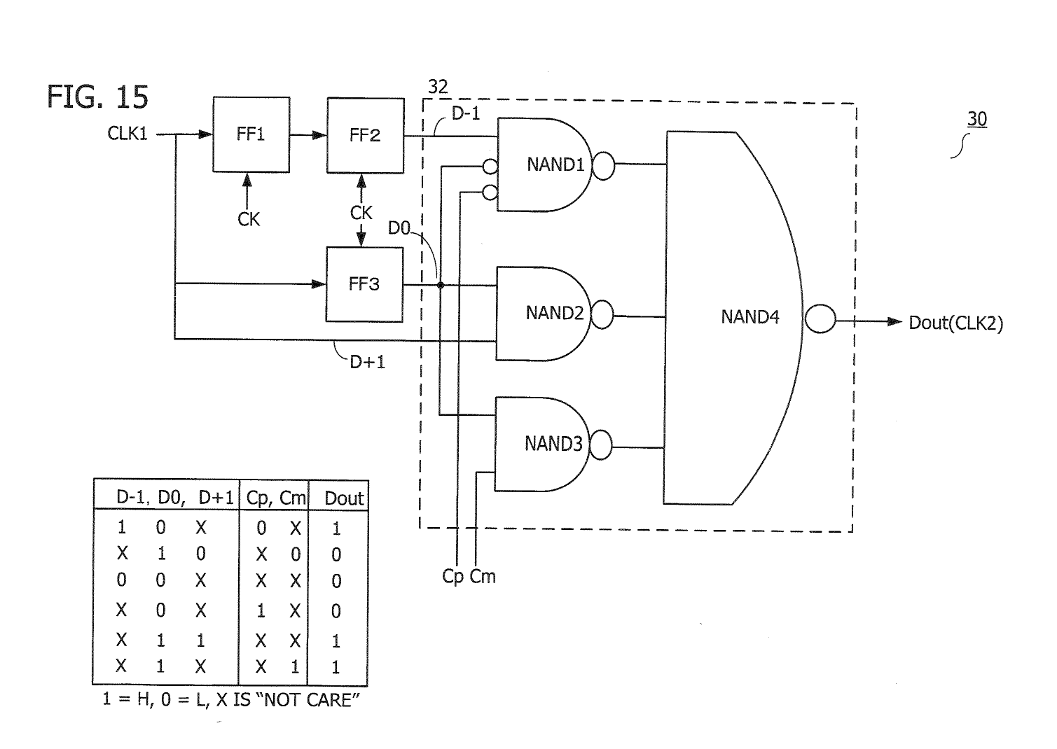

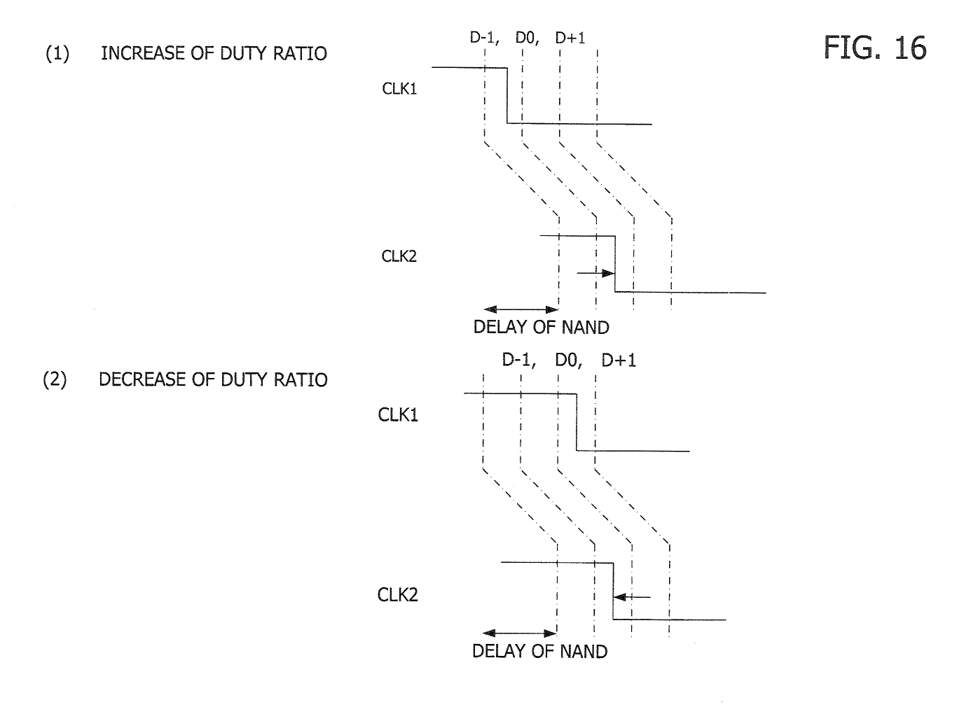

FIG. 15 is a block diagram depicting the clock duty control circuit 30 of the DAC according to the second embodiment. FIG. 16 is a diagram depicting the operation thereof. The clock duty control circuit 30 in FIG. 15 has flip-flops FF1, FF2 and FF3 which synchronize with the sampling clock CK, which is faster than clock CLK1. As FIG. 16 illustrates, the clock duty control circuit 30 outputs H(1) level or L(0) level of the clock CLK1 having three continuous timings of the sampling clock CK. The levels of the clock signal CLK1 at the three continuous timings are denoted with D−1, D0 and D+1 respectively.

The clock duty control circuit 30 has a duty ratio change circuit 32, which changes the control target level D0 of the clock CLK1 according to these levels of the clock single CLK1 at the three timings, and the adjustment signals Cp and Cm. The duty ratio change circuit 32 has four NANDs 1 to 4, and based on the levels D−1, D0 and D+1 at the three continuous sampling points of the clock signal CLK1, as illustrated in the logic value table in FIG. 15, the clock duty control circuit 30 changes the level D0 at the fall of the clock signal CLK1 from L to H to increase the pulse width, or from H to L to decrease the pulse width, or does not change the pulse width without changing the level D0, according to the adjustment signal Cp and Cm.

FIG. 16(1) illustrates a case of increasing the duty ratio, that is, increasing the pulse width. As illustrated in the first row of the logic value table of FIG. 15, if the replica analog signal Vout2 exceeds the reference voltage Vr+a and Cp=0 (L) when the clock signal CLK1 falls as D−1=1(H) and D0=0(L), the control target level D0 is changed from “0(L)” to “1(H)”, and is output. This change of the level D0 means increasing the pulse width of the clock CLK2.

FIG. 16(2) illustrates a case of decreasing the duty ratio, that is, decreasing the pulse width. As illustrated in the second row of the logic value table of FIG. 15, if the replica analog signal Vout2 is below the reference voltages Vr−α and Cm=0(L) when the clock signal CLK1 falls as D0=1(H), D+1=0(L), the control target level D0 is changed from “1(H)” to “0(L)”, and is output. This change of level D0 means decreasing the pulse width of the clock CLK2.

The third row of the logic value table illustrates that a clock does not fall between D−1 and D0, so the control target level D0=0 is not changed, and is output as Dout. In the fourth row of the logic value table, the clock falls, but adjustment signal Cp is Cp=1(H), so the control target level D0=0 is not changed, and is output as Dout.

The fifth row of the logic value table illustrates that a clock does not fall between D0 and D+1, so the control target level D0=1 is not changed, and is output as Dout. In the sixth row of the logic value table, the clock falls, but adjustment signal Cm is Cm=1(H), so the control target level D0=1 is not changed, and is output as Dout.

As described above, the DAC according to the second embodiment, in which the clock duty control circuit 30 is constituted by a logic circuit, does not require the operational amplifier and the comparator of the first embodiment.

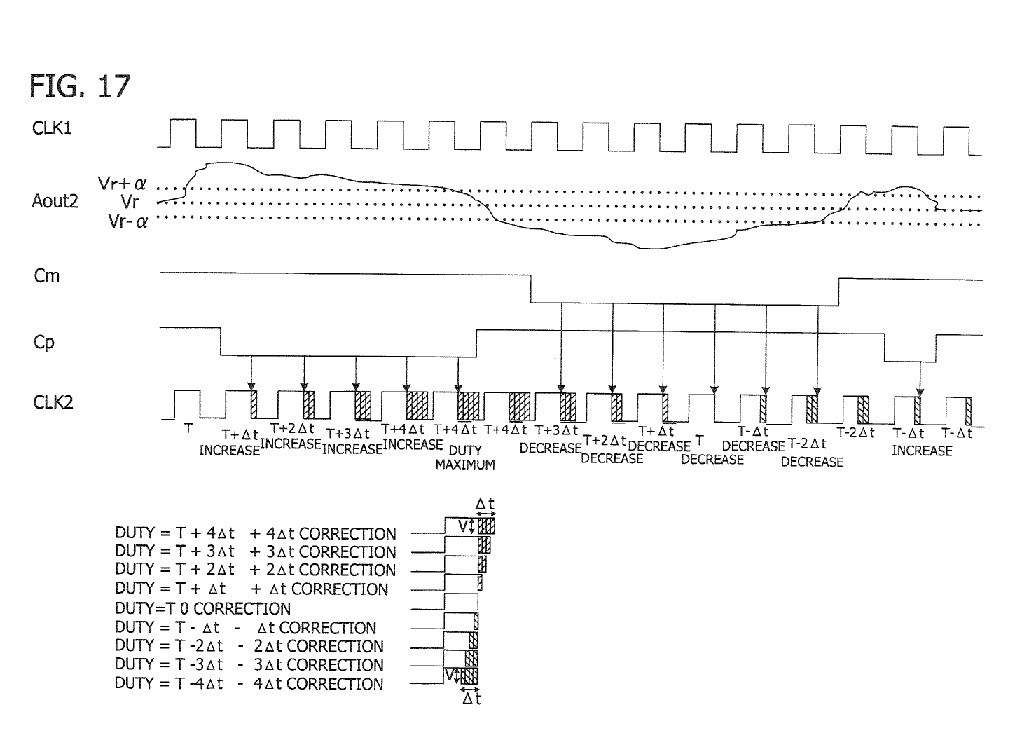

FIG. 17 is a diagram depicting a first variant form of the duty ratio control of the clock duty control circuit 30 of the DAC according to the second embodiment. In the case of the control example in FIG. 14, the pulse width of the clock signal CLK2 is increased or decreased by Δt, i.e. t+Δt or t−Δt. Whereas in the case of the example in FIG. 17, the pulse width of the clock signal CLK2 increases+Δt a time up to +4Δt while the adjustment signal Cp is Cp=L, and decreases −Δt a time down to −4Δt while the adjustment signal Cm is Cm=L. The pulse width is not changed when the adjustment signal Cp or Cm is H, which is the same as the example in FIG. 14.

In this first variant form, the duty ratio of the clock CLK2 is controlled in a wider range, and fluctuation of the analog signals is suppressed at higher precision. In the case of the first variant form, the clock duty control circuit 30 has the flip-flops FF1 to FF3 in FIG. 15, which are configured such that level D is determined at nine delay timings, from +4Δt to −4Δt and the duty ratio change circuit 32 detects the fall edges and increases/decreases the pulse width according to the adjustment signals Cp and Cm, like FIG. 15. The duty ratio change circuit 32 has a configuration such that the pulse width is increased/decreased up to/down to ±4Δt.

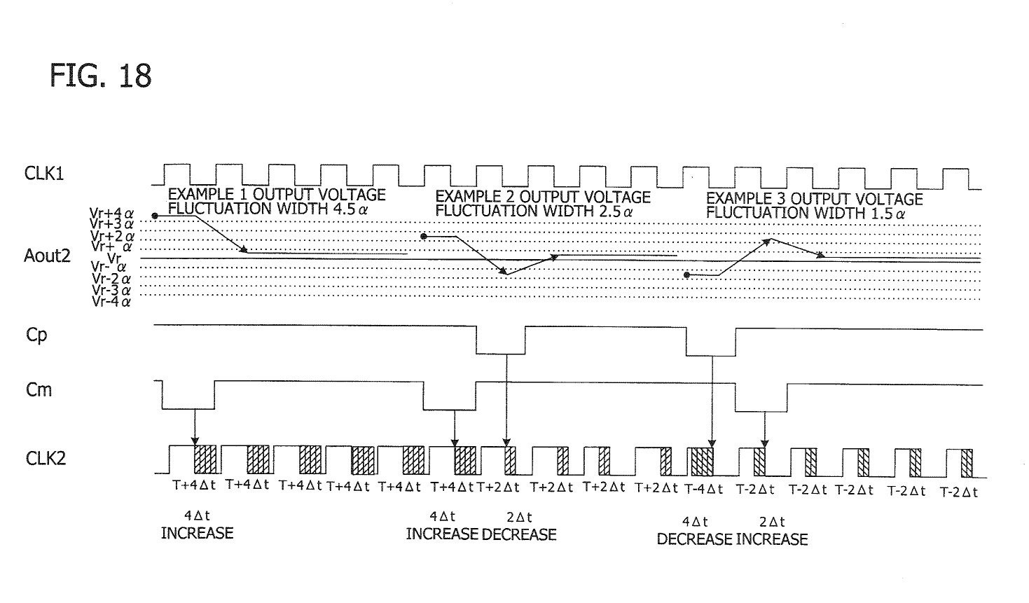

FIG. 18 is a diagram depicting a second variant form of the duty ratio control of the clock duty control circuit 30 of the DAC according to the second embodiment. In the case of the second variant form as well, the pulse width of the clock signal CLK2 is increased up to +4Δt, and is decreased down to −4Δt, like the first variant form. However an optimum pulse width is searched according to a binary search method, and if Cp becomes Cp=L or Cm becomes Cm=L from the Cp=H or Cm=H state, +4Δt is increased if Cp=L, or −4Δt is decreased if Cm=L, next the pulse width is changed by ±2Δt depending on whether Cp becomes L or Cm becomes L. If the pulse width is changed like this, an optimum pulse width may be reached by two times of a pulse width change.

FIG. 18 illustrates the pulse width change control in the cases of replica analog signal Aout2 changing +4.5α, +2.5α and −1.5α from reference voltage Vr. In Example 1, the optimum value in Vr±α is reached by one time of a pulse width change, and in Example 2 and Example 3, the optimum value is reached by two times of pulse width change.

In order to perform the duty ratio control in FIG. 18, the clock duty control circuit 30 has flip-flops FF1 to FF3 in FIG. 15, which are configured such that level D is determined at nine delay timings, from +4αt to −4αt, and the duty ratio change circuit 32 detects the fall edges, and increases or decreases the pulse width according to the adjustment signals Cp and Cm, like FIG. 15. The duty ratio change circuit 32 has a configuration such that the pulse width is changed in the sequence of ±4αt and ±2αt.

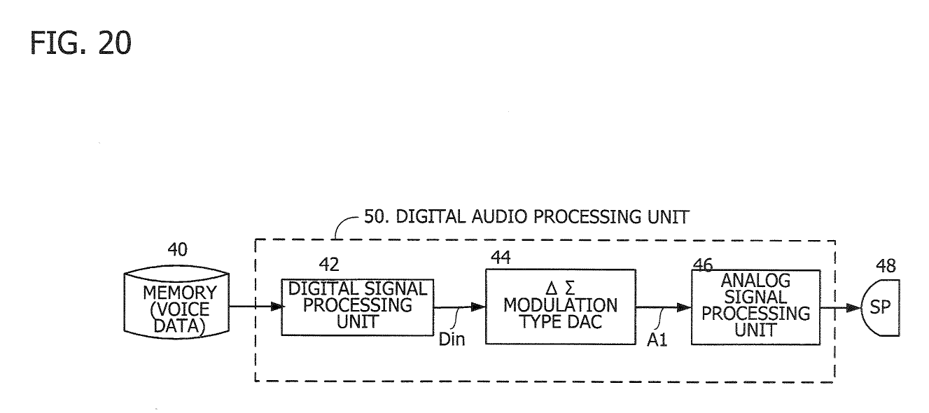

FIG. 20 is a block diagram of a digital audio processing circuit which has the ΔΣ modulation type DAC according to the first or second embodiment. The digital audio processing circuit 50 has the ΔΣ modulation type DAC 44, a digital signal processor 42 which reads the digital audio data from the storage 40 and inputs the digital audio data to the DAC 44 as the digital signal Din, and an analog signal processor 46 which supplies an analog signal A1 generated by the DAC 44 to such an audio regeneration circuit 48 as a speaker.

According to the digital analog conversion circuit of this embodiment, fluctuation of the output analog signals, due to power supply noise and clock skewing, is suppressed, and conversion increases accordingly.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention, have been described in detail, it should be understood that the various changes, substitutions, and alterations could be made hereto without departing from the spirit and scope of the invention.

What is claimed is:

1. A digital analog convertor, comprising:
a modulator which modulates a digital signal having a plurality of bits to generate a pulse signal having a pulse density corresponding to a digital value of the digital signal;
a first RZ conversion circuit which RZ-converts the pulse signal based on a first clock signal to generate a first RZ pulse signal;
a first integration circuit which integrates the first RZ pulse signal to output a first analog signal;
a second RZ conversion circuit which RZ-converts a first level signal having a first level of the pulse signal based on the first clock signal to generate a second RZ pulse signal;
a second integration circuit which integrates the second RZ pulse signal to output a second analog signal; and
a clock duty control circuit which controls a duty ratio of the first clock signal so that the second analog signal approaches a given reference level.

2. The digital analog convertor according to claim 1, wherein the first and second integration circuits comprise a first and second low pass filters which output the first and second analog signals according to pulse densities of the first and second RZ pulse signals respectively.

3. The digital analog convertor according to claim 1, wherein
the clock duty control circuit comprises:
a triangular wave generation circuit which generates a triangular wave based on a second clock signal; and
a comparator which compares the second analog signal with the triangular wave to generate the first clock signal.

4. The digital analog convertor according to claim 3, wherein the triangular wave generation circuit comprises a pull-up switch and a pull-down switch which is alternately turned ON or OFF by the second clock signal, and generates the triangular wave in a connection node of the pull-up switch and the pull-down switch.

5. The digital analog convertor according to claim 1, wherein
the clock duty control circuit comprises:
a triangular wave generation circuit which generates a triangular wave having a potential corresponding to a potential of the second analog signal based on a second clock signal; and
a comparator which compares the triangular wave with a reference voltage to generate the first clock signal.

6. The digital analog convertor according to claim 1, wherein the clock duty control circuit decreases or increases a pulse width of the first clock signal by a given width when a level of the second analog signal is higher than the reference level, and increases or decreases a pulse width of the first clock signal by a given width when the level of the second analog signal is lower than the reference level.

7. The digital analog convertor according to claim 6, wherein the clock duty control circuit repeats decreasing or increasing the pulse width of the first clock signal by a given width while the level of the second analog signal is higher than the reference level, and repeats increasing or decreasing the pulse width of the first clock signal by a given width while the level of the second analog signal is lower than the reference level.

8. The digital analog convertor according to claim 6, wherein
the reference level has a first reference level and a second reference level which is lower than the first reference level, and
the clock duty control circuit decreases or increases the pulse width of the first clock signal by a given width when the level of the second analog signal is higher than the first reference level of the reference levels, increases or decreases the pulse width of the first clock signal by a given width when the level of the second analog signal is lower than the second reference level of the reference levels, and maintains the pulse width of the first clock signal when the level of the second analog signal is between the first and second reference levels.

9. The digital analog convertor according to claim 8, wherein after the level of the second analog signal is changed to be higher than the first reference level or lower than the second reference level from a level between the first and second reference levels, the clock duty control circuit gradually decreases the given width from the maximum width until the level of the second analog signal returns to a level between the first and second reference levels.

10. The digital analog convertor according to claim 1, further comprising:
a first driver circuit, provided between the first RZ conversion circuit and the first integration circuit, which adjusts a waveform of the first RZ pulse signal; and
a second driver circuit, provided between the second RZ conversion circuit and the second integration circuit, which adjusts a waveform of the second RZ pulse signal.

11. A digital audio processing circuit, comprising:
the digital analog convertor according to claim 1;
a digital signal processor which reads digital audio data from a storage, and inputs the digital audio data into the digital analog convertor as the digital signal; and
an analog signal processor which supplies the first analog signal generated by the digital analog convertor to an audio regeneration circuit.

12. A method of adjusting digital analog conversion, the method comprising:
modulating a digital signal having a plurality of bits to generate a pulse signal having a pulse density corresponding to a digital value of the digital signal;
RZ-converting the pulse signal based on a first clock signal to generate a first RZ pulse signal;
integrating the first RZ pulse signal to output a first analog signal;
RZ-converting a first level signal having a first level of the pulse signal based on the first clock signal to generate a second RZ pulse signal;
integrating the second RZ pulse signal to output a second analog signal; and
controlling a duty ratio of the first clock signal so that the second analog signal approaches a given reference level.
